(19) United States
(12) Patent Application Publication
(10) Pub. No.: US 2011/0068834 A1
(43) Pub. Date: Mar. 24, 2011

(54) ELECTRO-MECHANICAL OSCILLATING DEVICES AND ASSOCIATED METHODS

(75) Inventors: Pritiraj Mohanty, Los Angeles, CA (US); Matthias Imboden, Rye, NH (US); Seung-Bo Shim, Gyeonggi-do (KR); Alexei Gaidarzhy, Boston, MA (US); Guiti Zolfagharkhani, Boston, MA (US); Robert L. Badzey, Quincy, MA (US)

(73) Assignee: Trustees of Boston University, Boston, MA (US)

(21) Appl. No.: 12/028,327

(22) Filed: Feb. 8, 2008

Related U.S. Application Data
(63) Continuation-in-part of application No. 11/813,342, filed on Nov. 13, 2008.
(60) Provisional application No. 60/919,656, filed on Mar. 23, 2007.
(60) Provisional application No. 60/642,400, filed on Jan. 7, 2005.

(51) Int. Cl. H03D 7/00

(52) U.S. Cl. 327/113

(57) ABSTRACT

Electro-mechanical oscillating devices designed to convert the frequency of electrical signal(s) and methods associated with the same are described. One example of such a frequency converting device is a mixer.

### CROSS REFERENCE TO RELATED APPLICATIONS

This application claims priority to U.S. Provisional Patent Application No. 60/919,656, filed Mar. 23, 2007. This application is also a continuation-in-part of U.S. patent application Ser. No. 11/813,342, filed Jul. 3, 2007 which is a national phase application based on International Patent Application Serial No. PCT/US2006/000401, filed Jan. 4, 2006, which claims priority to U.S. Provisional Patent Application No. 60/642,400, filed Jan. 7, 2005. All of these applications are incorporated herein by reference including International Publication No. WO 2006/083482 which is based on International Patent Application Serial No. PCT/US2006/000401.

### STATEMENT REGARDING FEDERALLY SPONSORED RESEARCH

This invention was made with Government Support under Contract Nos. CCF-0432089 and DMR-0449670 awarded by the National Science Foundation. This invention was also made with Government Support under Grant Number DMR-0346707 awarded by the National Science Foundation and Grant Number DAAD19-00-2-0004 awarded by the U.S. Army Research Office. The Government has certain rights in the invention.

### FIELD OF INVENTION

The present invention relates generally to electro-mechanical oscillating devices and more particularly to electro-mechanical oscillating devices designed to convert the frequency of electrical signal(s) and methods associated with the same.

### BACKGROUND OF INVENTION

There are many examples of devices that are used to convert the frequency of electrical signals. Such frequency converting devices may receive one or more input signals and may produce one or more output signals. In some cases, frequency converting devices increase frequency (i.e., “up convert”) and in other cases frequency converting devices decrease frequency (i.e., “down convert”).

One example of a frequency converting device is commonly referred to as a mixer. A mixer is a device that receives two input electrical signals having different frequencies and produces an output signal. The output signal is a mixture of the two input signals and can include frequencies corresponding to the sum of the frequency of the input signals and the difference between the frequencies of the input signals. Typically, one of the input signals received by the mixer is referred to as the local oscillator (LO), the other input signal is referred to as the carrier signal (RF) and the output signal is referred to as the intermediate frequency (IF).

Frequency converting devices have been produced in the form of MEMS devices. Such MEMS devices may include elements (i.e., mechanical oscillating elements) which are mechanically vibrated by an excitation source. The vibrational frequency of a mechanical oscillating element depends on the dimensions of the element, amongst other factors such as the material stiffness and density. The mechanical vibrations may be converted to an electrical signal using known techniques.

Electrical signals having frequencies in the gigahertz (GHz) range, or higher, are now used in many applications including wireless communications. MEMS devices have been limited in their ability to produce signals at such high frequencies. To generate such frequencies, mechanical oscillating elements typically would have a nanoscale dimension (e.g., less than 100 nm) parallel to the displacement during vibration, but such nanoscale elements typically vibrate at a small amplitude. Thus, the signal obtained from such vibrating nanoscale elements is often relatively weak and may be unsuitable for detection and/or further processing and/or transmission.

### SUMMARY OF INVENTION

Electro-mechanical oscillating devices designed to convert the frequency of electrical signal(s) and methods associated with the same are described.

In one aspect, a device designed to convert the frequency of a signal is provided. The device comprises a first mechanical oscillating element; and, a second mechanical oscillating element coupled to the first mechanical oscillating element. The device is adapted to convert the frequency of a carrier signal from a first frequency to a second frequency, and at least one of the first frequency or the second frequency is in the gigahertz range.

In another aspect, a device designed to convert the frequency of a signal is provided. The devices comprises a first major mechanical oscillating element and at least one minor mechanical oscillating element coupled to the first major mechanical oscillating element. The minor element has a large dimension in the submicron range. The device is adapted to convert the frequency of a carrier signal from a first frequency to a second frequency.

In another aspect, a method of converting the frequency of a carrier signal is provided. The method comprises converting a frequency of a carrier signal from a first frequency to a second frequency using a device comprising a first mechanical oscillating element, wherein at least one of the first frequency or the second frequency is greater than 1 GHz.

In another aspect, a method of converting the frequency of a carrier signal is provided. The method comprises converting a frequency of a carrier signal from a first frequency to a second frequency using a mixing device comprising at least one mechanical oscillating element having a large dimension in the submicron range.

In another aspect, a method of converting the frequency of an input signal is provided. The method comprises providing a single input signal having a first frequency to a mechanical oscillating element and converting the frequency of the input signal to form an output signal having a second frequency.

In another aspect, a method of converting the frequency of an input signal is provided. The method comprises providing a first input signal having a first frequency to a first mechanical oscillating element and providing a second input signal having a second frequency to a second mechanical oscillating element. The first mechanical oscillating element is coupled to the second mechanical oscillating element. The method further comprises producing an output signal having a third frequency.

In another aspect, a device is provided. The device is configured to convert the frequency of a single input signal having a first frequency provided to a mechanical oscillating element to form an output signal having a second frequency.

In another aspect, a frequency converting device is provided. The device is configured to have an first input signal having a first frequency provided to a first mechanical oscillating element and a second input signal having a second frequency provided to a second mechanical oscillating element. The first mechanical oscillating element is coupled to the second mechanical oscillating element. The device is configured to produce an output signal having a third frequency.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF THE DRAWINGS

FIG. 1 shows a mechanical oscillating device according to an embodiment of the present invention.

FIG. 2 shows a mechanical oscillating device according to an embodiment of the present invention.

FIG. 3 shows a mechanical oscillating device according to an embodiment of the present invention.

FIGS. 4A-4B are views of a mechanical oscillating device according to an embodiment of the present invention.

FIG. 5A-5D shows an H-shaped mechanical oscillating device and response of the same device according to embodiments of the present invention.

FIGS. 6A-6F are perspective views of a composite structure simulation driven at different frequencies as described in Example 1.

FIG. 7 is a graph of a calculated frequency response spectrum for a composite structure as described in Example 1.

FIG. 8 is a graph of a measured frequency response spectrum for a composite structure as described in Example 1.

FIG. 9 is a graph of a measured frequency response of a composite structure as described in Example 1.

FIG. 10 is a graph of a measured frequency response of a composite structure as described in Example 1.

FIG. 11 is a copy of a micrograph of the device structure described in Example 2.

FIGS. 12A and 12B are plots of resonant motion amplitude as a function of the excitation frequency for different driving amplitude as described in Example 2.

FIG. 13 is a plot of a response spectrum as driving power is applied as described in Example 2.

### DETAILED DESCRIPTION

Electro-mechanical oscillating devices designed to convert the frequency of electrical signal(s) and methods associated with the same are described. The devices include one or more elements (e.g., beams) that may be stimulated to mechanically vibrate by one or more input signals. These elements are generally referred to as mechanical oscillating elements. In many embodiments, the devices include mechanical oscillating elements coupled to one another such that the vibrational characteristics (e.g., frequency, amplitude) of one (or more) of the elements influences the vibrational characteristics of another element. As described further below, desired vibrational characteristics may be produced by selecting the dimensions, geometry and arrangement of the elements, amongst other parameters. The mechanical vibrations may be converted to an output electrical signal which can be detected and/or transmitted and/or further processed. The output, for example, may have a strong signal at high frequencies (e.g., greater than 100 MHz) enabling the devices to be used in many desirable applications including wireless communications.

It should be understood that mechanical oscillating elements of the devices may have a number of resonant modes over a range of frequencies including frequencies of greater than 100 MHz and/or in the gigahertz range, or higher such as within the terahertz range. This enables the devices to receive and/or transmit signals at such frequencies. In some embodiments, as described further below, the devices may have at least one input or at least one output signal having a frequency of greater than 100 MHz, or greater than 1 GHz (e.g., 1-10 GHz). In some cases, both the input signal(s) and the output signal(s) may have frequencies within these ranges. Desired frequencies may be generated and/or selected for transmission and/or further processing. In general, the resonant modes include vibrations of the different oscillating elements. Depending upon the shape of the elements, vibrational resonance can take the form of torsional, transverse, shear, longitudinal compression or tension, dilatational, rotational or flexural modes.

In some embodiments, the device includes multiple nanoscale mechanical oscillating elements (e.g., referred to herein as a “minor elements”) capable of vibrating at frequencies in the gigahertz range, or higher. The nanoscale elements may be coupled to a larger scale (e.g., micronscale) mechanical oscillating element (e.g., referred to herein as a “major element”) causing the larger scale element to vibrate at frequencies similar to the vibrational frequencies of the nanoscale elements (e.g., in the gigahertz range, or higher). Each nanoscale element contributes vibrational energy to the larger element which enables the larger element to vibrate at a higher amplitude than possible with only a single nanoscale element. The vibration of the larger scale element can produce an electrical signal, for example, in the gigahertz range (or higher) which has sufficient strength to be detected and/or effectively transmitted and/or further processed.

In general, the devices can be used to process one or more input signals to produce one or more desired output signals. The output signal(s) may be a non-linear response to the input signal(s). It should be understood that the frequency converting devices may have a single input and a single output; multiple inputs and multiple outputs; or a single input and multiple outputs; or multiple inputs and a single output.

In some embodiments, the frequency converting devices are mixers that receive two input electrical signals (e.g., a local oscillator, a carrier signal) having different frequencies and produce an output signal (e.g., an intermediate frequency). In some cases, one input signal may be provided to a first mechanical oscillating element and the second input signal may be provided to a second mechanical oscillating element which is coupled to the first element. The output signal includes contributions of both oscillating elements. As described further below, by selecting suitable dimensions, geometries and arrangements of the elements, a desired output signal may be produced. For example, the output signal may have a frequency that is up-converted or down-converted compared to the frequency of the carrier signal depending on the application. At least one of the signals may have a frequency in the gigahertz range (or higher), particularly when the device includes one or more of nanoscale oscillating elements. For example, one or more of the input signals may have a frequency of above 100 MHz or above 1 GHz, and the output signal may have a frequency of below 10 MHz (e.g., 1-10 MHz).

In some embodiments, the devices have a single input signal (i.e., carrier signal) having a first frequency (fᵢₙ) applied to a mechanical oscillating element, and the resulting output signal obtained has a second frequency (fₒᵤₜ). In some cases, the first frequency is within a relatively close range to the second frequency. For example, the first frequency may be between 0.1 and 10 times, or between 0.2 and 5 times, the second frequency. It may be preferable for the first frequency to be approximately equal to a rational fraction (e.g., ½, ⅓, ¼) of the fundamental frequency of the mechanical oscillating element. It also may be preferable for the second frequency to be approximately equal to the fundamental frequency of the mechanical oscillating element. Suitable devices for such frequency conversion are described further below. Example 2 describes results that further illustrate frequency conversion using devices of the invention.

It should be understood that the term “fundamental frequency” of a mechanical oscillating element as used herein has its standard meaning in the art and generally refers to the lowest natural frequency of the mechanical oscillating element for a given polarization of motion (e.g., transverse flexural, torsional). The fundamental frequency may also be referred to as the “first mode of vibration”. The “second mode of vibration” refers to the second lowest natural frequency of the mechanical oscillating element. The term “mechanical oscillating element” may refer to a single mechanical oscillating element or a combination of more than one mechanical oscillating element coupled to one another.

Using frequency converting devices of the invention, it is also possible to apply a first and a second input signal having different frequencies respectively to a first and second mechanical oscillating elements which are coupled to each other, to produce an output signal having a third frequency. It should be understood that one or more additional input signals may be applied and/or one or more additional output signals may be produced. In some embodiments, the first input signal has a frequency approximately equal to a first mode of vibration. The second input signal may have a frequency approximately equal to a second mode of vibration. It may be preferable for at least one of the input signals or the output signal to be greater than 100 MHz and/or greater than 1 GHz. In some embodiments, the output signal is less than 10 MHz. Suitable devices for such frequency conversion are described further below. Suitable frequency converting devices have been described in “Synchronized Oscillation in Coupled Nanomechanical Oscillators”, Science, Vol. 316, 6 Apr. 2007 which is incorporated herein by reference.

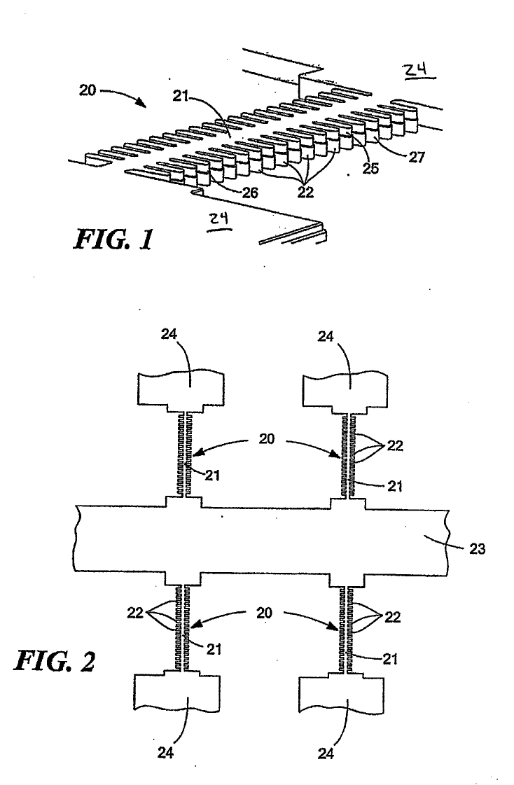

FIG. 1 shows a electro-mechanical oscillating device 20 according to an embodiment of the invention. Device 20 includes a composite structure of multiple minor elements 22 coupled to a major element 21. In this embodiment, elements 22 are in the form of cantilever beams and element 21 is in the form of a doubly-clamped beam which extends between two supports 24. During use, an input signal may be applied using a suitable excitation source which vibrates elements 22 at a high frequency (e.g., gigahertz range) and can influence the vibration of the major element 21 so that it also vibrates at a high frequency but with a larger amplitude than that of the individual minor elements, as described above. The mechanical vibration of the major element may be converted to an electrical signal which is transmitted or otherwise processed as desired.

In general, the minor elements have at least one smaller dimension (e.g., length, thickness, width) than the major element. In the illustrative embodiment, the minor elements have a shorter length than the major element. The minor elements may have submicron (i.e., less than 1 micron) dimensions. In some embodiments, at least one of the dimensions is less than 1 micron; and, in some embodiments, the “large dimension” (i.e., the largest of the dimensions) is less than 1 micron. For example, minor elements 22 may have a thickness and/or width of less than 1 micron (e.g., between 10 nm and 1 micron). Minor elements 22 may have a large dimension (e.g., length) between about 0.1 micron and 10 micron; or, between 0.1 micron and 1 micron. Major element 21 can have a width and/or thickness of less than 10 micron (e.g., between 10 nm and 10 micron). Major element 21 may have a length of greater than 1 micron (e.g., between 1 micron and 100 micron); in some cases, the major element has a length of greater than 10 micron (e.g., between 10 micron and 100 micron).

The dimensions of the major and minor elements are selected, in part, based on the desired performance including the desired frequency range of input and/or output signals associated with the device. It should be understood that dimensions outside the above-noted ranges may also be suitable. Suitable dimensions have also been described in International Publication No. WO 2006/083482 which is incorporated herein by reference.

It should also be understood that the major and/or minor elements may have any suitable shape and that the devices are not limited to beam-shaped elements. Other suitable shapes have been described in International Publication No. WO 2006/083482 which is incorporated herein by reference.

The total number of minor elements and major element(s) in the device and/or number of minor elements coupled to a major element may also be selected based on desired performance. In general, any suitable number of minor and major elements may be selected. For example, the ratio of the number of major elements to the number of minor elements in the device may be between 1:1 and 1:1,000; and, in some cases, between 1:10 and 1:100.

As noted above, one (or more) mechanical oscillating element of the device may be coupled to another (or more) mechanical oscillating element of the device. Though the coupling of the minor element to the major element in the embodiment of FIG. 1 is mechanical, it should be understood that other types of coupling may also be used. In general, any suitable coupling technique may be used including mechanical, electrical, electromagnetic or optical. When one element is coupled to another element that means the vibrational characteristics (e.g., frequency, amplitude) of at least one of the elements is influenced by the vibrational characteristics of the other element.

Any suitable excitation technique (also, referred to as an actuation source) may be used to vibrate the elements of device 20 including mechanical, electrostatic (i.e., capacitive), electromagnetic, piezoelectric and thermal expansion or contraction. These techniques may also be to detect the vibration of the elements and produce the desired output signal. In some cases, an electrostatic (i.e., capacitive) technique may be preferred. In some embodiments, a voltage is applied between electrodes associated with the device that leads to current flow, for example, across an oscillating element which, in the presence of a magnetic field, generates a force that causes the oscillating element to vibrate. The electrodes, for example, may be formed in part on supports 24. As shown in FIG. 1, a conducting layer 25 extends between the supports and may form part of an electrode and also forms a portion of the oscillating element(s). In other embodiments, the oscillating element(s) may be formed of a sufficiently conductive material to function as an electrode and a separate conducting layer may not be present on such elements.

It should be understood that combinations of the above-noted excitation and detection techniques can be used. For example, the elements of a device may be actuated electrostatically by applying a voltage between electrodes associated with the device which would cause the elements to move under electrostatic attraction, while the motion of the elements may be detected using piezoelectric techniques such as by measuring the piezoelectric voltage generated in portions of the elements under high strain due to their motion.

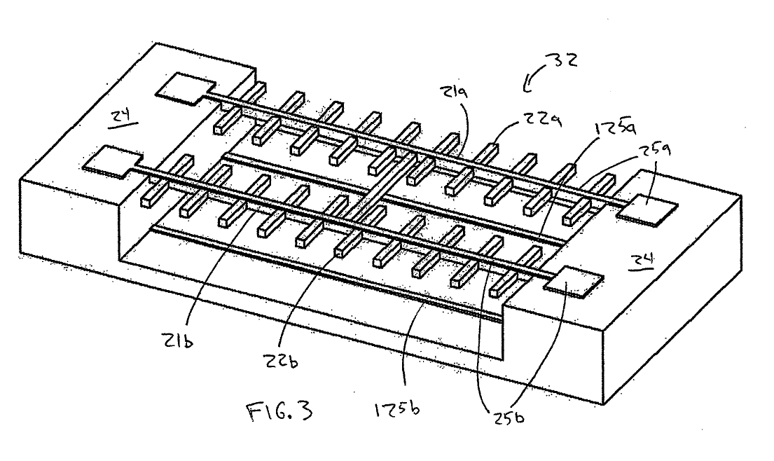

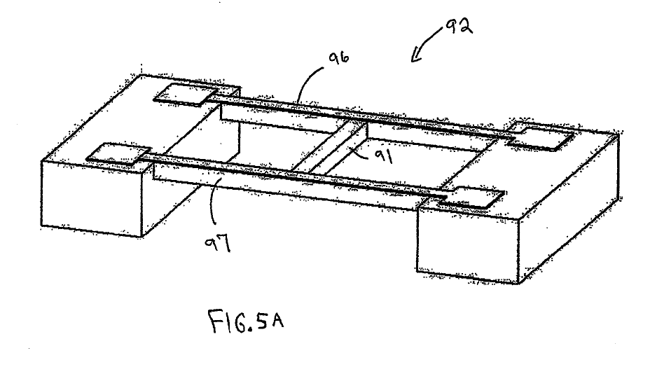

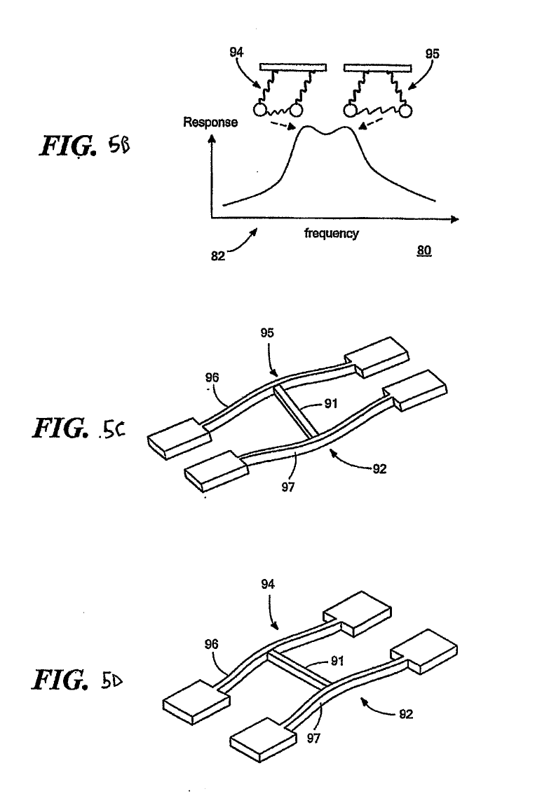

It should be understood that the devices may have large number of configurations and/or geometries. For example, FIGS. 3, 4A-4B and 5 illustrate other configurations as described further below. Many others are possible including suitable configurations described in International Publication No. WO 2006/083482 which is incorporated herein by reference. The geometry of the device can include, for example, any antenna type geometry, as well as beams, cantilevers, free-free bridges, free-clamped bridges, clamped-clamped bridges, discs, rings, prisms, cylinders, tubes, spheres, shells, springs, polygons, diaphragms and tori. Any of the mechanical oscillating and/or coupling elements may be formed either in whole or in part of the same or different geometries. In addition, several different type geometrical structures may be coupled together to obtain particular resonance mode responses. It should be understood that not all embodiments include major and minor mechanical oscillating elements. For example, the two mechanical oscillating elements shown in FIG. 5 are of similar dimension.

In some embodiments, the device may include a number of device structures (e.g., 20, FIG. 1) arranged in an array for utilization in a particular application, as shown in FIG. 2 and described in International Publication No. WO 2006/083482 which is incorporated herein by reference. The coupling of the different device structures in the array can be achieved according to a number of techniques, such as, for example, mechanical, electrical, electromagnetic or optical. An input signal may be transmitted coherently through the array, and may be manipulated by the elements of the array. For example, the array may perform an up/down conversion of an incoming signal in relation to a carrier signal.

In general, the device structures 20 can be addressed individually through separate electrodes, or can be addressed communally through a common electrode 23 as shown in FIG. 2. Alternately, or in addition, an electrode may be composed of separate traces to permit each oscillating beam to be isolated from the other. According to such an embodiment, each beam can be addressed individually at different potentials, and with different DC offsets, for example. In addition, or alternately, one device structure can be joined in parallel or serially to another device structure to permit such structures to act as circuit components in a larger circuit. In addition, or alternately, one or more structures can be particularly tuned for specific characteristics such as particular resonance frequencies.

FIG. 3 shows a electro-mechanical oscillating device 32 according to an embodiment of the invention. The device includes two major elements 21a, 21b that are coupled together using a mechanical coupling element 34. As in FIG. 1, minor elements 22a, 22b in the form of cantilever beams are respectively coupled to major elements 21a, 21b.

Depending on the intended use, input signals may be provided to device 30 in a number of ways and output signals may be produced in a number of ways. However, it should be understood that the ways are not limited to those embodiments described in the following paragraphs.

In some embodiments, a first input signal at a first frequency (e.g., local oscillator) may be provided to elements 21a, 22a by causing such elements to vibrate in the presence of an applied potential difference between electrode 25a (formed on element 21a) and bottom electrode 125b. A second input signal at a second frequency (e.g., RF carrier) may be provided to elements 21b, 22b by causing such elements to vibrate in the presence of an applied potential difference between electrode 25a (formed on element 22a) and bottom electrode 125b. In these embodiments, the device may function as a mixer by providing an output signal at the sum or difference of the two input frequencies due to the nonlinear mechanical coupling between the two sets of oscillating elements 21a/22a and 21b/22b. The output signal (e.g., intermediate frequency) may be detected on either bottom electrodes 125a, 125b in this embodiment.

In some embodiments, only a single input signal is provided to elements 21a, 22a; or to elements 21b, 22b. In these embodiments, the elements to which the signal is applied vibrate and their vibration influences the elements to which the signal is not applied because the elements are coupled. As described above, in some cases, a single input signal having a first frequency (fᵢₙ) and the resulting output signal obtained has a second frequency (fₒᵤₜ).

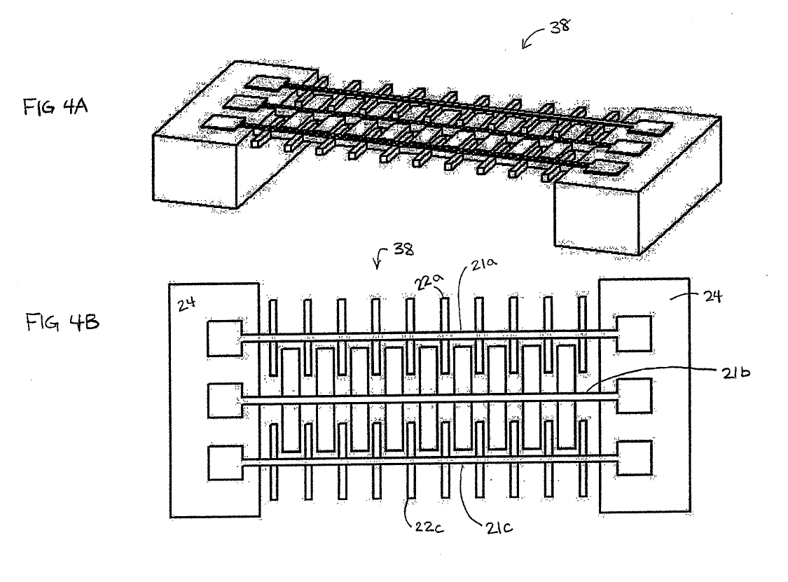

FIGS. 4A and 4B show different views of a device 38 according to an embodiment of the invention. The device includes three major elements 21a, 21b, 21c to which respective minor elements are coupled. The major elements are coupled to one another using an electro-static (e.g., capacitive) coupling mechanism. In some embodiments, major element 21b functions as a static coupling element. For example, a variable voltage may be placed on major element 21b which causes elements 21a and 21b to mechanically vibrate.

Depending on the intended use, input signals may be provided to device 38 in a number of ways and output signals may be produced in a number of ways including those described above.

FIG. 5 shows a device 92 according to an embodiment of the invention. The device is H-shaped and includes two doubly-clamped beams 96, 97 joined with a mechanical coupling element (e.g., a flexible bridge) 91. In this embodiment, no minor elements are shown coupled to beams 96, 97. However, in some H-shaped devices, it should be understood that one or more minor elements may be coupled to one or both of beams 96, 97.

Referring now to FIGS. 5B-5D, a diagram 80 illustrates a relationship between symmetric and anti-symmetric modes of device 92. The device can be tuned to create a bandpass filter, as illustrated in graph 82 of diagram 80. FIGS. 5C-5D illustrate doubly clamped coupled beams 92 joined with a flexible bridge 91. FIG. 5C represents an anti-symmetric mode 95 in which doubly clamped beams 96, 97 are oscillating out of phase with each other. FIG. 5D represents a symmetric oscillation mode 94 in which doubly clamped coupled beams 96, 97 oscillate in phase with each other. The two different modes, symmetric mode 94 and anti-symmetric mode 95, represent frequency ranges in combination that can be tuned by adjustment of the dimensions of the composite structure 92, as well as the spring constant of bridge 91. The frequencies of symmetric mode 94 and anti-symmetric mode 95 can also be tuned with the addition of particularly characterized bridges to enable the design and placement of band pass frequencies. Accordingly, a single structure with a ladder type geometry can be used to produce a device that can amplify higher resonance modes generated through the collective motion of major and minor elements in a gigahertz oscillator. The relative proximity of the symmetric and anti-symmetric modes in the frequency domain establishes an effective bandpass filter. The shape of the passband can be modified with the addition of major and/or minor element arrays to obtain, for example, a flatter passband and more effective filter. The coupling, or intermediate elements, such as bridge 91, tend to mediate the interaction between the major and minor elements to permit an increase in signal fidelity amplification and response. The coupling or intermediate elements also demonstrate mechanical mixing, in which the major elements generate sum and difference signals from an input at two or more different frequencies. The precise coupling of major and minor elements in a predetermined relationship provide a unique method for designing filters and mixers with nanoscale devices operating in a gigahertz range with high precision and repeatability.

The coupling or intermediate elements also demonstrate mechanical mixing, in which the major elements generate sum and difference signals from an input at two or more different frequencies. The precise coupling of major and minor elements in a predetermined relationship provide a unique method for designing filters and mixers with nanoscale devices operating in a gigahertz range with high precision and repeatability.

According to an embodiment of the present invention, the device is forced into or designed to have a nonlinear response to generate a mixed mode behavior. The nonlinear device demonstrates signal up or down conversion, where a high frequency carrier signal is converted to a signal of lower frequency for processing and analysis, or vice versa. While non linear elements have been used in electrical RF circuits to obtain up down conversion, the present invention provides a mechanical realization to produce the same result. The nonlinear device is also suitable for use as an amplifier circuit with a tunable bandwidth. The degree to which modes are mixed is related to the nonlinear drive of the device, so that tuning the mode mixing to include or exclude certain frequencies or bands of frequencies is readily achieved. Any suitable material may be used to form the components of devices described herein. Suitable materials include pure metals, metallic alloys, alternative semiconductor compositions such as silicon carbide (SiC), diamond, metal/semiconductor compounds or combinations of the above. Quartz or other related materials may also be used for piezoelectric actuation and detection. The devices may be composed of materials such as silicon, diamond, quartz, gallium arsenide (GaAs), gallium nitride (GaN), silicon carbide (SiC), silicon nitride (SiN), pure metals, bimetallic strips, heterogeneous semiconductor and metal compositions and heterogeneous compositions of two or more semiconductor materials.

Devices described herein may be fabricated according to a number of techniques taken from the semiconductor industry. The composite structure can be defined through lithographic techniques using an electron beam source. Photolithography can also be used to obtain the appropriate precision and desired device dimensions, especially if more recent deep-UV source and mask technology is used. Structure definition and release of the structure are accomplished in accordance with an exemplary embodiment through reactive ion etching (RIE) and hydrofluoric acid (HF) wet etch and critical point drying. These fabrication steps are established within the semiconductor industry, so that the device in accordance with the present invention may be constructed readily and without great expense.

The following are non-limiting examples that illustrate certain embodiments of the invention.

### Example 1

This example illustrates characterization of a mechanical oscillating device according to an embodiment. The characterization is based on simulations and measurements associated with a mechanical oscillating device similar to that illustrated in FIG. 1.

For the simulations and the measurements, the oscillating device had the following features. Major element 21 had a length of 10.7 micron, a thickness of 250 nm and a width of 400 nm. Minor elements 22 had a length of 500 nm, a cross-sectional dimension of 250 nm and a width of 250 nm. There are approximately 40 total minor elements arranged in a dual 20-element array on either side of the major element. The device includes a gold electrode 25 as a top layer, which has a thickness of approximately 85 nm. The device also includes a thin (5 nm) layer 26 composed of chromium interposed between gold electrode layer 25 and a silicon layer 27 to contribute to electrode adhesion between layer 25 and layer 27.

FIGS. 6A-6F show various modes of vibration for a device 20 based on a finite element simulation. The calculated resonance frequencies for each of the illustrated modes is indicated for each device. The simulation illustrations for oscillating frequencies above 400 MHz demonstrate phase locked oscillation of the minor elements. The phase locked oscillation of the minor elements contributes to providing the high frequency, high amplitude motion of the major element, for detection of resonance frequency.

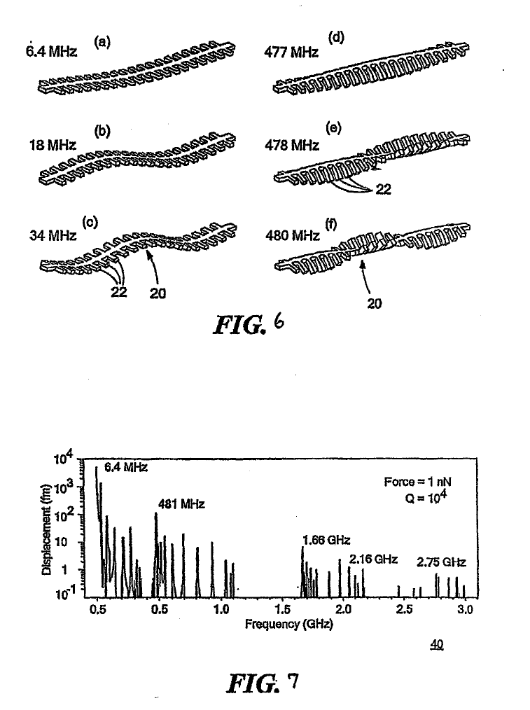

FIG. 7 is a graph 40 of a calculated frequency response spectrum. The calculations resulting in graph 40 are derived from a finite element simulation, as illustrated in FIGS. 6A-6F. As can be seen in the higher frequency range of graph 40, a number of high order resonance modes of significant amplitude are available for frequency generation. The spectrum of frequencies also illustrates a grouping phenomena, in which different families of resonance modes are observed.

FIG. 8 is a graph 50 of a measured frequency response spectrum based on the device. Graph 50 illustrates a number of strong resonance peaks at frequencies that compare closely with those obtained in the finite element simulation. An interesting aspect of the high frequency peaks observed in the resonance modes at 1.88 GHz and 2.35 GHz is their closeness to active frequencies for digital cellular and wireless communications.

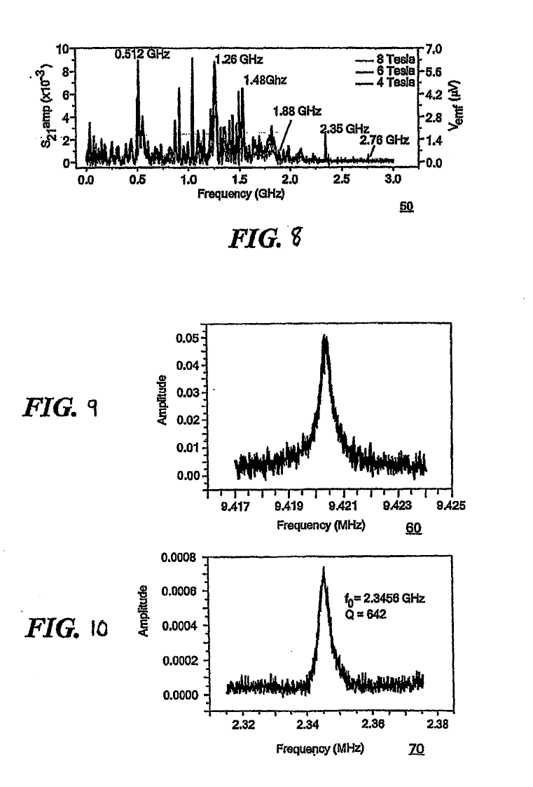

FIG. 9 is a graph 60 that illustrates a strong resonance frequency peak at approximately 9.4 MHz for the device. The peak at the relatively low frequency of 9.4 MHz corresponds to the excitation of the fundamental transverse vibrational mode of the major element with an additional impact related to mass loading due to the presence of minor elements.

FIG. 10 is a graph 70 that illustrates a measured frequency response for the device at a high frequency of approximately 2.3456 GHz. A higher frequency derived from the motion of composite structure 20 is a result of vibrational excitation of a high order collective mode in which the major element and the minor elements cooperate to attain an overall resonance mode. As noted above, the resonance frequency peak illustrated in graph 70 is close to the wireless communication standard frequency of 2.4 GHz.

### Example 2

This example illustrates characterization of a small-scale electro-mechanical frequency converter according to an embodiment.

FIG. 11 is a copy of a microscopic image of the device. The device nano-mechanical device is fabricated from single crystal silicon using e-beam lithography and surface micro-machining. The device includes two suspended beams, which constitute the two resonating elements. The two beams are clamped at each end to rigid support pads. The beams are 10 microns in length and 0.5 micron in width and thickness. Both beams have a 0.05 micron layer of metal deposited on them, which constitutes the conducting electrodes (labeled a-b and c-d in FIG. 10) used for electrical actuating and detection. The coupling element is another 5 microns-long mechanical beam that is attached at the midpoints of the resonating beams. The coupling beam carries no metal electrode, thereby reducing the coupling to purely mechanical elastic motion.

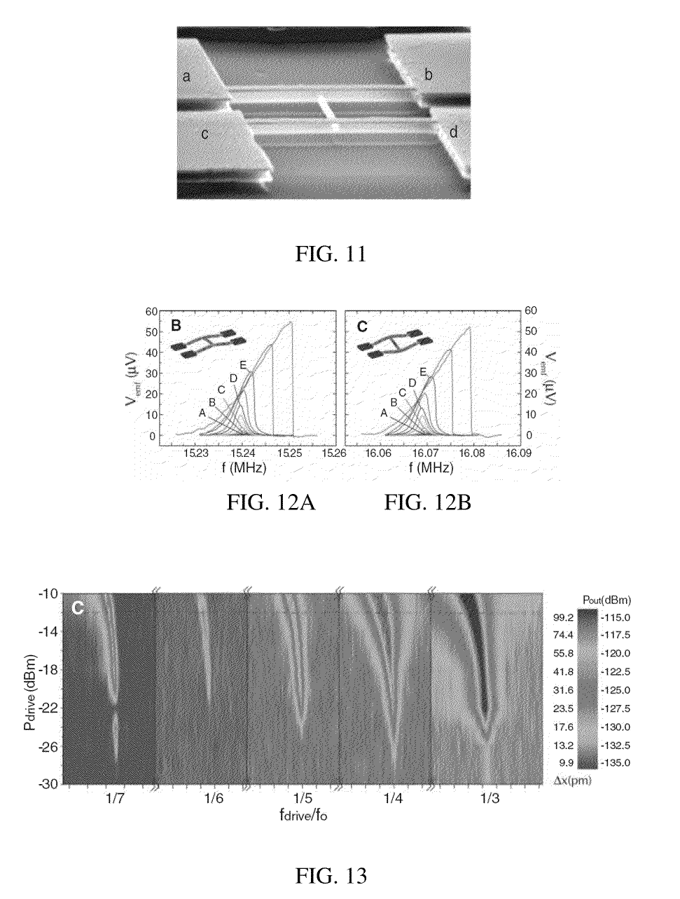

The dynamic mechanical motion of the two-element resonator device consisted primarily of two fundamental resonance modes, which are the preferred natural modes that have well-defined vibration frequencies. The two resonance modes, symmetric and anti-symmetric, were simulated numerically using finite element software, and the associated mode shapes are pictures as insets in FIGS. 12A and 12B. As predicted, measurements of the vibration spectrum of the actual device revealed two fundamental resonance peaks at 15.24 MHz and 16.07 MHz. Plots of the resonant motion amplitude as a function of the excitation frequency are presented in FIGS. 12A and 12B for different driving amplitudes. As the driving amplitude is increased, the motion of the structure in each mode becomes nonlinear, and the resonance peaks assume the characteristic asymmetric nonlinear shape, with a sharp drop on the right side that defines the bistability region.

The effect of frequency up- or down-conversion using this device was demonstrated as follows. A driving signal at a single input frequency fᵢₙ was applied on one of the resonating elements (electrode a-b on FIG. 11). The amplitude of the driving signal was adjusted to be large enough to put the resonating structure in the non-linear regime (see plots in FIGS. 12A and 12B). The response of the resonating structure was measured by detecting the output signal on the other resonating beam (electrode c-d) at precisely the frequency of one of the fundamental modes of the structure, in this case the symmetric f_{sym}=15.24 MHz mode. For frequency up-conversion, the input frequency fᵢₙ was tuned at one-half of the resonance frequency, such that fᵢₙ=½f_{sym}, and the device generated an output signal at precisely f_{sym}. For frequency down-conversion, the input frequency fᵢₙ was tuned at twice the resonance frequency, such that fᵢₙ=2f_{sym}, and the device generated an output signal at precisely f_{sym}. This method works in general for any input frequency fᵢₙ=a/b f_{sym}, where a and b are any small integers.

FIG. 13 is a plot of a response spectrum as driving power is applied near the rational fractions of the fundamental frequency f₀. The lighter regions indicate generation of the output signal at f₀ by the device, thereby up-converting the original input frequency.

It will further be appreciated by those of ordinary skill in the art that modifications to and variations of the above described switching systems may be made without departing from the inventive concepts disclosed herein. Accordingly, the invention should not be viewed as limited except as by the scope and spirit of the appended claims.

What is claimed is:

1. A device designed to convert the frequency of a signal comprising:
a first mechanical oscillating element; and
a second mechanical oscillating element coupled to the first mechanical oscillating element,
wherein the device is adapted to convert the frequency of a carrier signal from a first frequency to a second frequency, and at least one of the first frequency or the second frequency is in the gigahertz range.

2. The device of claim 1, wherein the device converts the frequency of the carrier signal by combining the carrier signal with a second signal.

3. The device of claim 1, wherein the first mechanical oscillating element comprises a beam and the second mechanical oscillating element comprises a beam.

4. The device of claim 3, wherein the first mechanical oscillating element comprises a doubly-clamped beam.

5. The device of claim 1, further comprising a coupling element that mechanically couples the first mechanical oscillating element to the second mechanical oscillating element.

6. The device of claim 5, wherein the coupling element is connected to the first mechanical oscillating element and the second mechanical oscillating element at respective positions approximately at nodes or anti-nodes of the first mechanical oscillating element and the second mechanical oscillating element.

7. The device of claim 1, further comprising mechanical oscillating minor elements coupled to at least one of the first mechanical oscillating element or second mechanical oscillating element, the minor elements having a large dimension in the submicron range.

8. The device of claim 7, wherein the minor elements have a large dimension between 0.1 micron and 1 micron.

9. The device of claim 1, wherein the first mechanical oscillating element and the second mechanical oscillating element have a large dimension in the micron range.

10. The device of claim 1, wherein the first mechanical oscillating element and the second mechanical oscillating element have a large dimension between 1 micron and 100 micron.

11. The device of claim 1, wherein one of the first mechanical oscillating element and the second mechanical oscillating element have a large dimension in the submicron range.

12. The device of claim 1 further comprising mechanical oscillating minor elements coupled to at least one of the first mechanical oscillating element or the second mechanical oscillating elements, wherein the minor elements have a large dimension between 0.1 micron and 10 micron.

13. A device designed to convert the frequency of a signal comprising:
a first major mechanical oscillating element; and
at least one minor mechanical oscillating element coupled to the first major mechanical oscillating element, the minor element having a large dimension in the submicron range,
wherein the device is adapted to convert the frequency of a carrier signal from a first frequency to a second frequency.

14. The device of claim 13, wherein the device converts the frequency of the carrier signal by combining the carrier signal with a second signal.

15. The device of claim 13, further comprising a plurality of minor mechanical oscillating elements coupled to the first mechanical oscillating element, the minor elements having a large dimension in the submicron range.

16. The device of claim 13, further comprising a second major mechanical oscillating element coupled to the first major mechanical oscillating element.

17. A method of converting the frequency of a carrier signal comprising:
converting a frequency of a carrier signal from a first frequency to a second frequency using a device comprising a first mechanical oscillating element, wherein at least one of the first frequency or the second frequency is greater than 1 GHz.

18. The method of claim 17, wherein at least one of the first frequency or the second frequency is within the gigahertz range.

19. The method of claim 17, wherein the first frequency is greater than 1 GHz.

20. The method of claim 17, wherein the first frequency is greater than the second frequency.

21. The method of claim 17, wherein the second frequency is within the gigahertz range.

22. The method of claim 17, wherein the second frequency is greater than the first frequency.

23. The method of claim 17, further comprising a second mechanical oscillating element coupled to the first mechanical oscillating element.

24. The method of claim 17, comprising a plurality of mechanical oscillating elements having a large dimension in the submicron range.

25. A method of converting the frequency of a carrier signal comprising:
converting a frequency of a carrier signal from a first frequency to a second frequency using a mixing device comprising at least one mechanical oscillating element having a large dimension in the submicron range.

26. A method of converting the frequency of an input signal comprising:
providing a single input signal having a first frequency to a mechanical oscillating element; and
converting the frequency of the input signal to form an output signal having a second frequency.

27. The method of claim 26, wherein the first frequency is between 0.1 and 10 times the second frequency.

28. The method of claim 26, wherein the first frequency is between 0.5 and 5 times the second frequency.

29. The method of claim 26, wherein the first frequency is approximately equal to a rational fraction of a fundamental frequency of the mechanical oscillating element.

30. The method of claim 26, wherein the second frequency is approximately equal to a fundamental frequency of the mechanical oscillating element.

31. The method of claim 26, wherein the first frequency and the second frequency are greater than 1 GHz.

32. The method of claim 26, wherein the mechanical oscillating element comprises a beam.

33. The method of claim 26, wherein the mechanical oscillating element is coupled to a second mechanical oscillating element.

34. A method of converting the frequency of an input signal comprising:
providing a first input signal having a first frequency to a first mechanical oscillating element;
providing a second input signal having a second frequency to a second mechanical oscillating element, wherein the first mechanical oscillating element is coupled to the second mechanical oscillating element; and
producing an output signal having a third frequency.

35. The method of claim 34, wherein the first input signal has a first frequency approximately equal to a first mode of vibration.

36. The method of claim 34, wherein the second input signal has a second frequency approximately equal to a second mode of vibration.

37. The method of claim 34, further comprising providing at least one more input signal and producing at least one more output signal.

38. The method of claim 34, wherein at least one of the first frequency, second frequency and third frequency is greater than 100 MHz.

39. The method of claim 34, wherein at least one of the first frequency, second frequency and third frequency is greater than 1 GHz.

40. The method of claim 34, wherein the third frequency is below 10 MHz.

41. A device configured to convert the frequency of a single input signal having a first frequency provided to a mechanical oscillating element to form an output signal having a second frequency.

42. A frequency converting device configured to have an first input signal having a first frequency provided to a first mechanical oscillating element and a second input signal having a second frequency provided to a second mechanical oscillating element,
wherein the first mechanical oscillating element is coupled to the second mechanical oscillating element and the device is configured to produce an output signal having a third frequency.
